(19) United States
(12) Patent Application Publication
(10) Pub. No.: US 2026/0268046 A1
(43) Pub. Date: Sep. 10, 2026

(54) LANGUAGE-CONDITIONED TRAJECTORY DIFFUSION FOR CLOSED-LOOP TRAFFIC SIMULATION

(71) Applicant: NEC Laboratories America, Inc., Princeton, NJ (US)

(72) Inventors: Francesco Pittaluga, Los Angeles, CA (US); Wei-Jer Chang, Fremont, CA (US)

(21) Appl. No.: 19/554,981

(22) Filed: Mar. 3, 2026

Related U.S. Application Data
(60) Provisional application No. 63/768,161, filed on Mar. 6, 2025.

(51) Int. Cl. G06F 30/27

(52) U.S. Cl. CPC G06F 30/27

(57) ABSTRACT

Systems and methods for language-conditioned trajectory diffusion for closed-loop traffic simulation. Multi-modality scene context information that includes map information and agent information for agents in input videos can be captured with a language-conditioned trajectory diffusion simulation (LTDS) model. Spatiotemporal scene information can be extracted based on semantic information from text instructions with the LTDS model. The map information, agent information, and semantic information can be fused using a cross-attention fusion module of the LTDS model into text-conditioned encodings. Language-conditioned trajectories can be generated based on the text-conditioned encodings with a text-conditioned diffusion model of the LTDS model. Closed-loop training of the text-conditioned diffusion model can be performed while performing downstream tasks based on the language-conditioned trajectories.

### RELATED APPLICATION INFORMATION

This application claims priority to U.S. Provisional App. No. 63/768,161, filed on Mar. 6, 2025, incorporated herein by reference in its entirety.

### BACKGROUND

### Technical Field

The present invention relates to multi-modality processing with artificial intelligence (AI) and more particularly to language-conditioned trajectory diffusion for closed-loop traffic simulation.

### Description of the Related Art

AI models have been progressing in a rapid state due to their popularity. AI models have been used for image processing and text processing. However, processing multiple modalities such as images and texts is still a developing field.

### SUMMARY

According to an aspect of the present invention, a method is provided including, capturing multi-modality scene context information that includes map information and agent information for agents in input videos with a language-conditioned trajectory diffusion simulation (LTDS) model, extracting spatiotemporal scene information based on semantic information from text instructions with the LTDS model, fusing the map information, agent information, and semantic information using a cross-attention fusion module of the LTDS model into text-conditioned encodings, generating language-conditioned trajectories based on the text-conditioned encodings with a text-conditioned diffusion model of the LTDS model, and performing closed-loop training of the text-conditioned diffusion model while performing downstream tasks based on the language-conditioned trajectories.

According to another aspect of the present invention, a system is provided including a memory device, one or more processor devices operatively coupled with the memory device to perform operations including, capturing multi-modality scene context information that includes map information and agent information for agents in input videos with a language-conditioned trajectory diffusion simulation (LTDS) model, extracting spatiotemporal scene information based on semantic information from text instructions with the LTDS model, fusing the map information, agent information, and semantic information using a cross-attention fusion module of the LTDS model into text-conditioned encodings, generating language-conditioned trajectories based on the text-conditioned encodings with a text-conditioned diffusion model of the LTDS model, and performing closed-loop training of the text-conditioned diffusion model while performing downstream tasks based on the language-conditioned trajectories.

According to yet another aspect of the present invention, a non-transitory computer program product is provided including a computer-readable storage medium including a program code, wherein the program code when executed on a computer causes the computer to perform operations including, capturing multi-modality scene context information that includes map information and agent information for agents in input videos with a language-conditioned trajectory diffusion simulation (LTDS) model, extracting spatiotemporal scene information based on semantic information from text instructions with the LTDS model, fusing the map information, agent information, and semantic information using a cross-attention fusion module of the LTDS model into text-conditioned encodings, generating language-conditioned trajectories based on the text-conditioned encodings with a text-conditioned diffusion model of the LTDS model, and performing closed-loop training of the text-conditioned diffusion model while performing downstream tasks based on the language-conditioned trajectories.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a block diagram that shows a system for language-conditioned trajectory diffusion for closed-loop traffic simulation, in accordance with an embodiment of the present invention;

FIG. 2 is a block diagram that shows a computer system for language-conditioned trajectory diffusion for closed-loop traffic simulation, in accordance with an embodiment of the present invention;

FIG. 3 is a block diagram that shows hardware and software components of a computer system for language-conditioned trajectory diffusion for closed-loop traffic simulation, in accordance with an embodiment of the present invention;

FIG. 4 is a block diagram that shows components of the text-conditioned diffusion model for language-conditioned trajectory diffusion for closed-loop traffic simulation, in accordance with an embodiment of the present invention;

FIG. 5 is a flow diagram that shows a high-level overview of language-conditioned trajectory diffusion for closed-loop traffic simulation, in accordance with an embodiment of the present invention;

FIG. 6 is a block diagram that shows a practical application of language-conditioned trajectory diffusion for closed-loop traffic simulation, in accordance with an embodiment of the present invention; and

FIG. 7 is a block diagram that shows closed-loop training for language-conditioned trajectory diffusion for closed-loop traffic simulation, in accordance with an embodiment of the present invention.

### DETAILED DESCRIPTION OF PREFERRED EMBODIMENTS

In accordance with embodiments of the present invention, systems and methods are provided for language-conditioned trajectory diffusion for closed-loop traffic simulation.

In the present embodiments, multi-modality scene context information that includes map information and agent information for agents in input videos can be captured with a language-conditioned trajectory diffusion simulation (LTDS) model.

Spatiotemporal scene information can be extracted based on semantic information from text instructions with the LTDS model. The map information, agent information, and semantic information can be fused using a cross-attention fusion module of the LTDS model into text-conditioned encodings. Language-conditioned trajectories can be generated based on the text-conditioned encodings with a text-conditioned diffusion model of the LTDS model. Closed-loop training of the text-conditioned diffusion model can be performed while performing downstream tasks based on the language-conditioned trajectories.

Traffic simulation is essential for the safe and scalable development of autonomous vehicles (AVs). By simulating interactions among multiple traffic participants, it enables AVs to handle a wide range of realistic scenarios. This approach is critical for at least the following reasons: it accelerates development by enabling large-scale, repeatable testing in controlled environments, it provides structured testing to validate vehicle behavior across diverse conditions, and it allows AVs to train for real-world complexities, improving safety and reliability. A key aspect of simulation is controllability: the ability to model the interactive behavior of other road users, which AVs can learn to navigate and respond to safely and effectively.

Traditionally, structured testing of AVs has relied on manually designed scenarios to simulate potential failure cases, such as collisions. While effective for targeted testing, this approach is inherently limited in scalability. Recent advances in diffusion-based generative models demonstrate strong capabilities in simulating complex distributions with flexible controllability, though this often depends on domain-specific heuristic guidance functions constructed based on human knowledge post-training.

Trajectory diffusion models can be utilized for traffic simulation. Typically, trajectory diffusion models are trained in an open-loop fashion. However, this mismatch between training and inference can lead to distribution shifts, where the model encounters compounding errors due to deviations from the expected trajectory distribution. A common approach to mitigate this issue during inference is to apply guidance methods or hard constraints to steer model predictions toward physically feasible behaviors. However, these techniques slow down inference speed and require careful balancing of multiple objectives, limiting adaptability in real-time simulations. In contrast, closed-loop training is a widely used technique for mitigating compounding errors in closed-loop rollouts, as seen in autoregressive models, where past predictions are recursively used as input to better reflect real-world deployment scenarios. However, applying closed-loop training to diffusion models presents a unique challenge as it is computationally expensive to incorporate self-generated states into training.

The present embodiments resolve the issues for simulations for AVs with a language-controlled diffusion-based trajectory simulation model and associated training strategy. This model incorporates a unique combination of multimodal embeddings—high definition (HD) map, agent histories, and text—to guide trajectory generation with language prompts. It supports closed-loop training and safety-critical simulations, effectively combining textual inputs with guidance mechanisms to control agent behaviors. This approach enables accurate and controllable simulations of complex multi-agent interactions and single-agent behaviors based on language instructions. By doing so, the present embodiments reduce the system complexity of training diffusion models while generating inferences. Additionally, the present embodiments reduce the storage and computational resources utilized in the training as language-conditioned trajectories can be generated while performing downstream tasks.

Embodiments described herein may be entirely hardware, entirely software or including both hardware and software elements. In a preferred embodiment, the present invention is implemented in software, which includes but is not limited to firmware, resident software, microcode, etc.

Embodiments may include a computer program product accessible from a computer-usable or computer-readable medium providing program code for use by or in connection with a computer or any instruction execution system. A computer-usable or computer readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a computer-readable storage medium such as a semiconductor or solid state memory, magnetic tape, a removable computer diskette, a random access memory (RAM), a read-only memory (ROM), a rigid magnetic disk and an optical disk, etc.

Each computer program may be tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

These and other variations of a hardware processor subsystem are also contemplated in accordance with embodiments of the present invention.

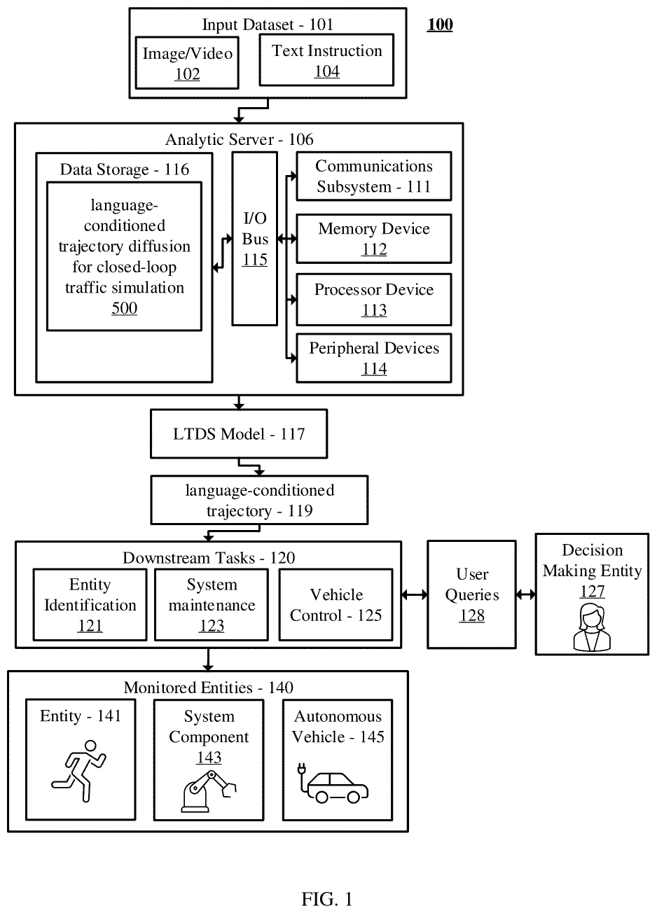

Referring now in detail to the figures in which like numerals represent the same or similar elements and initially to FIG. 1, a block diagram shows a system for language-conditioned trajectory diffusion for closed-loop traffic simulation, in accordance with an embodiment of the present invention.

In an embodiment using a system 100, monitored entities 140 can include entity 141, system component 143, and autonomous vehicle 145. The monitored entities 140 can generate an input dataset 101. The input dataset 101 can include image/video 102, and text instructions 104. The input dataset 101 can be transmitted to an analytic server 106 that can implement language-conditioned trajectory diffusion for closed-loop traffic simulation 500. The analytic server 106 can obtain a language-controlled diffusion-based trajectory simulation (LTDS) model 117 that can generate language-conditioned trajectories 119 which can be utilized to perform downstream tasks 120.

System 100 can be utilized to perform downstream tasks 120 based on the input dataset 101 and user queries 128 from a decision-making entity 127. The downstream tasks 120 can include entity identification 121, system maintenance 123, and vehicle control 125. The analytic server 106 can generate a corrective action for the downstream tasks 120 to be sent to respective computing systems for the monitored entities 140 through a network.

In entity identification 121, the input dataset 101 (e.g., location images, scene images, entity images such as parts of the entity, etc.) related to the entity 141 can be processed by the analysis server 106 to answer user queries 128. The user queries 128 can be relevant to the entity 141 such as their attributes (e.g., position, direction of movement, color of clothing, etc.), relationship with other entities within a scene (e.g., proximity, behavior, etc.), relationship with the environment, etc. The LTDS model 117 can predict future attributes, and relationships of the entity 141.

Based on the predictions of the LTDS model 117, a corrective action can be generated by the LTDS model 117. The corrective action can include notifying the decision making entity 127 of the predictions about the entity 141 based on their input dataset 101, generating resolutions to an issue caused by the entity (e.g., the entity 141 as a disabled vehicle in a traffic scene and the resolution is the deployment of a repair technician, etc.) of the input dataset 101 to help with the decision making process of the decision making entity 127, etc.

In system maintenance 123, input dataset 101 (e.g., system logs, test cases, hardware status images, etc.) related to the system component 143 can be processed to answer user queries 128. The user queries 128 can be relevant on how to properly maintain the system component 143 based on the input dataset 101. A corrective action can be generated by the analytic server 106 which can include the answer to the user queries 128 (e.g., determine causes to bandwidth issues, etc.) to maintain the system component 143. Based on the corrective action (e.g., adding bandwidth, blocking packets from an identified internet protocol (IP) address to resolve malicious attacks, restarting hardware, etc.) the network system can be autonomously maintained.

In vehicle control 125, input dataset 101 (e.g., vehicle part status, traffic scene image, etc.) related to the autonomous vehicle 145 can be processed to answer user queries 128. The user queries 128 can be relevant to how to control the autonomous vehicle 145 given its environment based on the input dataset 101. A corrective action can be generated by the analytic server 106 which can include the answer to the user queries 128 to control the proper performance of the autonomous vehicle 145. Based on the corrective action (e.g., stopping, speeding up, changing direction, etc.) the autonomous vehicle 145 can be autonomously controlled using appropriate control devices (e.g., advanced driver assistance systems, braking device, accelerator device, cooling device, etc.) within the autonomous vehicle. In an embodiment, the autonomous vehicle 145 can be controlled in response to avoid a predicted event based on a generated trajectory such as multi-vehicle collision, accidents, detected road hazards, etc.

In another embodiment, in vehicle control 125, the autonomous vehicle 145 can be controlled to verify and test the functionality of the various components (e.g., advanced driver assistance systems, braking device, accelerator device, cooling device, etc.) of the autonomous vehicle 145 by autonomously controlling the components and generate test data that can be used to fine-tune/train the LTDS model 117.

Other downstream tasks and practical applications are contemplated.

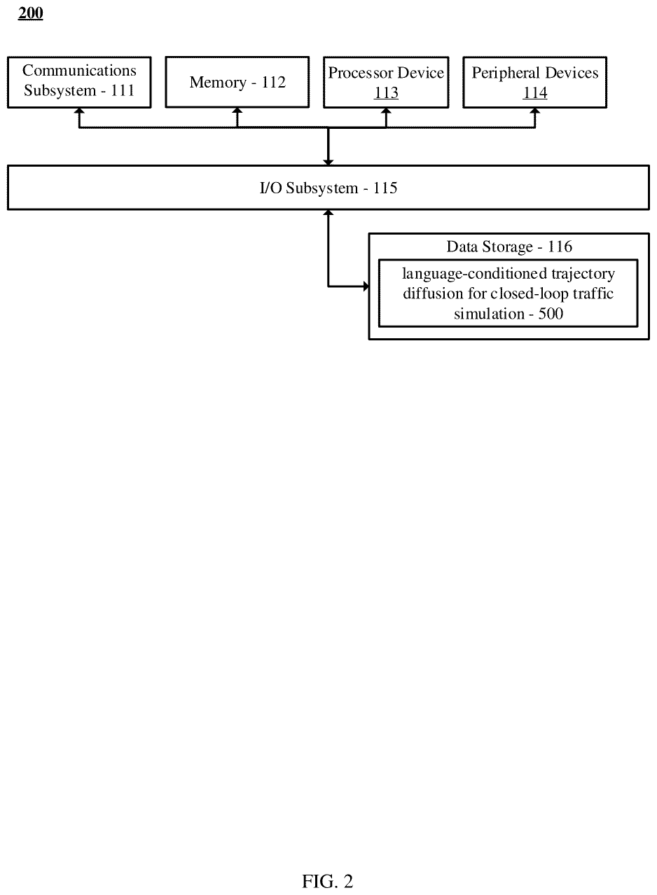

The analytic server 106 can include a processor device 113, data storage device 116, memory 112, communications subsystem 111, peripheral devices 114, and input/output (I/O) bus 115. The analytic server 106 is an implementation of a computer system. Other implementations are contemplated. The computer system is shown in more detail in FIG. 2.

Referring now to FIG. 2, a block diagram shows a computer system for language-conditioned trajectory diffusion for closed-loop traffic simulation, in accordance with an embodiment of the present invention.

The computing device 200 illustratively includes the processor device 113, an input/output (I/O) subsystem 190, a memory 112, a data storage device 116, and a communications subsystem 111, and/or other components and devices commonly found in a server or similar computing device. The computing device 200 may include other or additional components, such as those commonly found in a server computer (e.g., various input/output devices), in other embodiments. Additionally, in some embodiments, one or more of the illustrative components may be incorporated in, or otherwise form a portion of, another component. For example, the memory 112, or portions thereof, may be incorporated in the processor device 113 in some embodiments.

The processor device 113 may be embodied as any type of processor capable of performing the functions described herein. The processor device 113 may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s).

The memory 112 may be embodied as any type of volatile or non-volatile memory or data storage capable of performing the functions described herein. In operation, the memory 112 may store various data and software employed during operation of the computing device 200, such as operating systems, applications, programs, libraries, and drivers. The memory 112 is communicatively coupled to the processor device 113 via the I/O subsystem 115, which may be embodied as circuitry and/or components to facilitate input/output operations with the processor device 113, the memory 112, and other components of the computing device 200. For example, the I/O subsystem 115 may be embodied as, or otherwise include, memory controller hubs, input/output control hubs, platform controller hubs, extracted control circuitry, firmware devices, communication links (e.g., point-to-point links, bus links, wires, cables, light guides, printed circuit board traces, etc.), and/or other components and subsystems to facilitate the input/output operations. In some embodiments, the I/O subsystem 115 may form a portion of a system-on-a-chip (SOC) and be incorporated, along with the processor device 113, the memory 112, and other components of the computing device 200, on a single extracted circuit chip.

The data storage device 116 may be embodied as any type of device or devices configured for short-term or long-term storage of data such as, for example, memory devices and circuits, memory cards, hard disk drives, solid state drives, or other data storage devices. The data storage device 116 can store program code for language-conditioned trajectory diffusion for closed-loop traffic simulation 500. Any or all of these program code blocks may be included in a given computing system.

The communications subsystem 111 of the computing device 200 may be embodied as any network interface controller or other communication circuit, device, or collection thereof, capable of enabling communications between the computing device 200 and other remote devices over a network. The communications subsystem 111 may be configured to employ any one or more communication technology (e.g., wired or wireless communications) and associated protocols (e.g., Ethernet, InfiniBand®, Bluetooth®, Wi-Fi®, WiMAX, etc.) to effect such communication.

As shown, the computing device 200 may also include one or more peripheral devices 114. The peripheral devices 114 may include any number of additional input/output devices, interface devices, and/or other peripheral devices. For example, in some embodiments, the peripheral devices 114 may include a display, touch screen, graphics circuitry, keyboard, mouse, speaker system, microphone, network interface, and/or other input/output devices, interface devices, GPS, camera, and/or other peripheral devices.

Of course, the computing device 200 may also include other elements (not shown), as readily contemplated by one of skill in the art, as well as omit certain elements. For example, various other sensors, input devices, and/or output devices can be included in computing device 200, depending upon the particular implementation of the same, as readily understood by one of ordinary skill in the art. For example, various types of wireless and/or wired input and/or output devices can be employed. Moreover, additional processors, controllers, memories, and so forth, in various configurations can also be utilized. These and other variations of the computing device 200 are readily contemplated by one of ordinary skill in the art given the teachings of the present invention provided herein.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific extracted circuits (ASICs), field-programmable gate arrays (FPGAs), and/or programmable logic arrays (PLAs).

These and other variations of a hardware processor subsystem are also contemplated in accordance with embodiments of the present invention.

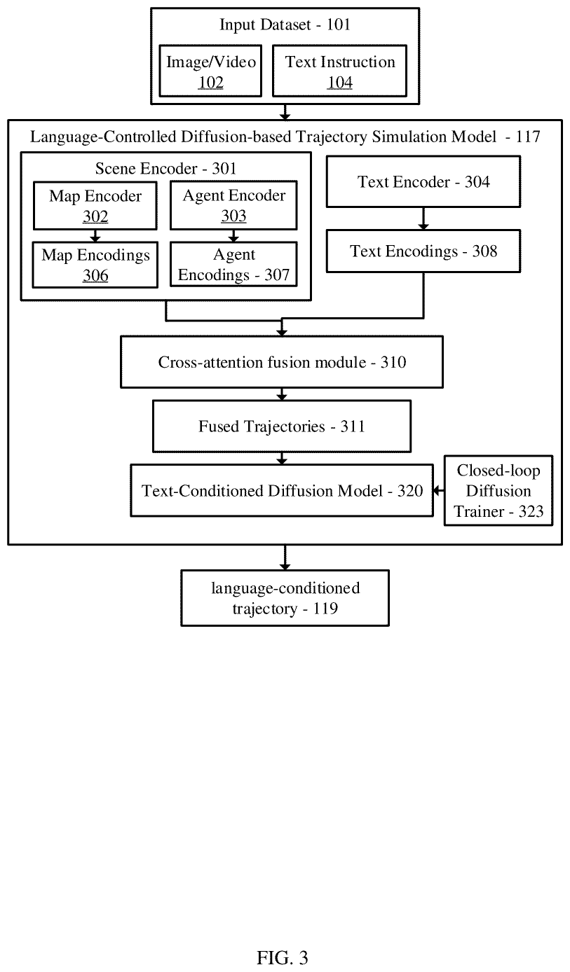

Referring now to FIG. 3, a block diagram shows hardware and software components of a computer system for language-conditioned trajectory diffusion for closed-loop traffic simulation, in accordance with an embodiment of the present invention.

In an embodiment, a language-controlled diffusion-based trajectory simulation (LTDS) model 117 can be employed to generate language-conditioned trajectories that can be used for downstream tasks 120. The LTDS model 117 can include a scene encoder 301 and a text encoder 304.

The scene encoder 301 can include a map encoder 302 and an agent encoder 303. The map encoder 302 can encode data from image/video 102 to obtain map encodings 306. The agent encoder 303 can encode data from image/video 102 to obtain agent encodings 307.

The text encoder 304 can encode data from the text instruction 104 to obtain text encodings 308.

The text encodings 308, agent encodings 307, and map encodings 306 can be fused with the cross-attention fusion module 310 to obtain fused trajectories 311.

The fused trajectories 311 can be analyzed by the text-conditioned diffusion model 320 to obtain language-conditioned trajectories 119. The text-conditioned diffusion model 320 can be trained by a closed-loop diffusion trainer 323.

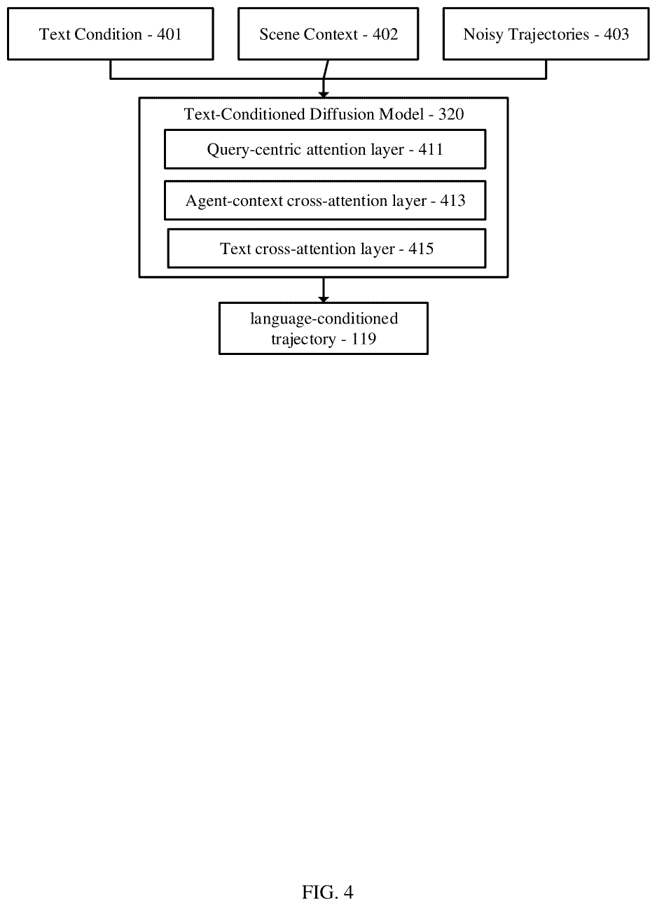

Referring now to FIG. 4, a block diagram shows components of the text-conditioned diffusion model for language-conditioned trajectory diffusion for closed-loop traffic simulation, in accordance with an embodiment of the present invention.

In an embodiment, the text-conditioned diffusion model 320 can process text condition 401, scene context 402, and noisy trajectories 403 to generate language-conditioned trajectory 119. The text condition 401 can be based on text instruction 104. The scene context 402 can be based on outputs of the scene encoder 301. The noisy trajectories 403 can be based on the fused trajectories 311 that were augmented with noise.

The text-conditioned diffusion model 320 can include a query-centric attention layer 411, agent-context cross-attention layer 413, and text cross-attention layer 415.

The query-centric attention layer 411 capture inter-agent relationships, allowing each agent to attend to other agents' future actions.

The agent-context cross-attention layer 413 where each agent attends to its context embedding generated by the Scene Encoder 301, ensuring that the agent's behavior aligns with the spatiotemporal context of the environment.

The text cross-attention layer 415 where if a language description is provided, each agent also attends to the language-conditioned embedding generated by the cross-attention fusion model 310, incorporating condition from text instruction 104. The LTDS model 117 utilizes neural networks.

A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the inputted data belongs to each of the classes can be output.

The empirical data, also known as training data, from a set of examples can be formatted as a string of values and fed into the input of the neural network. Each example may be associated with a known result or output. Each example can be represented as a pair, (x, y), where x represents the input data and y represents the known output. The input data may include a variety of different data types and may include multiple distinct values. The network can have one input neurons for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

The deep neural network, such as a multilayer perceptron, can have an input layer of source neurons, one or more computation layer(s) having one or more computation neurons, and an output layer, where there is a single output neuron for each possible category into which the input example could be classified. An input layer can have a number of source neurons equal to the number of data values in the input data. The computation neurons in the computation layer(s) can also be referred to as hidden layers, because they are between the source neurons and output neuron(s) and are not directly observed. Each neuron in a computation layer generates a linear combination of weighted values from the values output from the neurons in a previous layer, and applies a non-linear activation function that is differentiable over the range of the linear combination. The weights applied to the value from each previous neuron can be denoted, for example, by w₁, w₂, . . . wₙ₋₁, wₙ. The output layer provides the overall response of the network to the inputted data. A deep neural network can be fully connected, where each neuron in a computational layer is connected to all other neurons in the previous layer, or may have other configurations of connections between layers. If links between neurons are missing, the network is referred to as partially connected.

Training a deep neural network can involve two phases, a forward phase where the weights of each neuron are fixed and the input propagates through the network, and a backwards phase where an error value is propagated backwards through the network and weight values are updated. The computation neurons in the one or more computation (hidden) layer(s) perform a nonlinear transformation on the input data that generates a feature space. The classes or categories may be more easily separated in the feature space than in the original data space.

In an embodiment, the neural network 300 of the LTDS model 117 can be trained to update hidden states configured for generating language-conditioned trajectories 119. In an embodiment, the neural network of the cross-attention fusion module 310 can be trained to update hidden states configured for generating fused trajectories 311. In an embodiment, the neural network of the scene encoder 301 can be trained to update hidden states configured for generating map encodings 306 with the map encoder 302. In an embodiment, the neural network of the scene encoder 301 can be trained to update hidden states configured for generating agent encodings 307 with the agent encoder 303. In an embodiment, the neural network of the text encoder 304 can be trained to update hidden states configured for generating text encodings 308. In an embodiment, the closed-loop diffusion trainer 323 can update model parameters of the text-conditioned diffusion model 320 based on the language-conditioned trajectory 119 generated for downstream tasks.

In another embodiment, the present embodiments can utilize categorical annotations as a base for training. To diversify language during training, the present embodiments can leverage a large-language model to generate 20 rephrasings of each annotated behavior, expanding the range of language variations encountered by the model.

In another embodiment, the present embodiments can apply a biased sampling approach to balance the training data. Specifically, the present embodiments can unsample human-annotated samples to represent 50% of the training batch. Additionally, the present embodiments can randomly select 30% of the heuristic descriptions during training. This can allow simultaneous training of the language-conditioned and unconditional diffusion models, which can optimize both modes effectively.

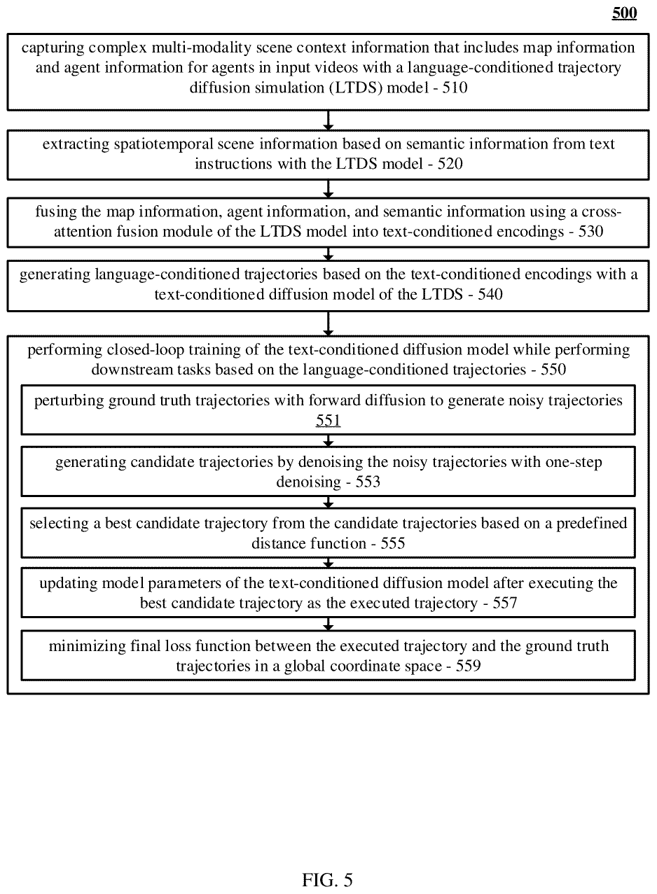

Referring now to FIG. 5, a flow diagram shows a high-level overview of language-conditioned trajectory diffusion for closed-loop traffic simulation, in accordance with an embodiment of the present invention.

In an embodiment, multi-modality scene context information that includes map information and agent information for agents in input videos can be captured with a language-conditioned trajectory diffusion simulation (LTDS) model. Spatiotemporal scene information can be extracted based on semantic information from text instructions with the LTDS model. fusing the map information, agent information, and semantic information using a cross-attention fusion module of the LTDS model into text-conditioned encodings. Language-conditioned trajectories can be generated based on the text-conditioned encodings with a text-conditioned diffusion model of the LTDS model. Closed-loop training of the text-conditioned diffusion model can be performed while performing downstream tasks based on the language-conditioned trajectories.

In traffic simulation, the present embodiments can model N agents, each directed by a function g that governs their behavior within the environment. A language-conditioned simulation can be simulated and generated where all agents exhibit both realistic and controllable behaviors. By conditioning each agent on language instructions, represented as a symbolic input e_{lang}, the present embodiments can enable the agents' behavior to align to user inputs. In practice, the present embodiments can replace one agent, by ego planning policy, which the present embodiments can want to evaluate, and use e_{lang} to control agent's behavior for structured testing.

In block 510, multi-modality scene context information that includes map information and agent information for agents in input videos can be captured with a language-conditioned trajectory diffusion simulation (LTDS) model.

In an embodiment, multi-modality scene context information that includes map information and agent information for agents in input videos can be captured with a language-conditioned trajectory diffusion simulation (LTDS) model by encoding map information and agent action history symmetrically from the traffic scene into map encodings 306 and agent encodings 307 for each agent through a symmetric encoder such as the scene encoder 301 which includes map encoder 302 and agent encoder 303. The present embodiments can utilize the query-centric approach to encode relative relationships between elements (map, agent position histories) that employs a shared context encoder to capture complex multimodal scene context information for all agents.

The map information can include data regarding the traffic scene such as the road, placement of the traffic lights, placement of other entities (e.g., trees, buildings, benches, etc.).

The agent information can include agent action, agent position, and states.

In an embodiment, agent actions can be represented based on the states of the agents for each timestep.

To encode the agent actions, at each timestep t, the states of all N vehicles are denoted as

$${s}_{t} = [ {s}_{t}^{1} , … , {s}_{t}^{N} ] ,$$

where each

$${s}_{t}^{i} = ( {x}_{t}^{i} , {y}_{t}^{i} , {v}_{t}^{i} , {θ}_{t}^{i} ) , {x}_{t}^{i} , {y}_{t}^{i}$$

represents the 2D position of the x and y axis,

$${v}_{t}^{i}$$

represents the speed, and

$${θ}_{t}^{i}$$

represents the yaw of vehicle i. The corresponding actions for each vehicle are given by

$${a}_{t} = [ {a}_{t}^{1} , … , {a}_{t}^{N} ]$$

with

$${a}_{t}^{i} = ( {\dot{v}}_{t}^{i} , {\dot{θ}}_{t}^{i} ) , {\dot{v}}_{t}^{i}$$

representing acceleration, and

$${\dot{θ}}_{t}^{i}$$

representing yaw rate. A transition function f predicts the next state at timestep t+1, computed as sₜ₊₁=ƒ(sₜ, aₜ), following unicycle dynamics.

In an embodiment, agent actions can be guided with a shared context based on historical states of neighboring agents.

Each agent's decision-making is guided by a shared context cₜ, which includes a map view I, the historical states of neighboring vehicles over the past Tₕᵢₛₜ timesteps (from t−Tₕᵢₛₜ to t), denoted as s_{t-T}_{ₕᵢₛₜ}_{:t}={s_{t-T}_{ₕᵢₛₜ}, . . . , sₜ}, and the language symbol e_{lang} that conveys user-specified directives. This shared context cₜ provides each agent with a consistent view of the environment and its expectations, allowing behaviors to align with user intentions.

In block 520, spatiotemporal scene information can be extracted based on semantic information from text instructions with the LTDS model.

In an embodiment, the semantic information can include context and relationship between tokens that can be extracted from text instructions 104 which can represent explicit agent-specific conditioning and spatiotemporal scene information. For example, the text instructions 104 can include “Let ego vehicle stop and yield to another vehicle.” The text instructions 104 can be tokenized into instruction tokens with a tokenizer. The instruction tokens can be encoded by the text encoder 304 into text encodings 308.

The text encodings 308 can include context embedding and positional embedding. The context embedding can include the context and relationship between tokens from the text instructions 104. The positional embedding can be obtained from the map encodings 306 generated by the scene encoder 301. The text encodings 308 can be generated by augmenting the context embedding with positional embeddings and a class token embedding for the text encoder 304.

The text encoder 304 can utilize a language encoder framework such as bidirectional encoder representations from transformers (BERT) that utilizes low-rank adaptation (LoRA). Other frameworks can be utilized.

For each agent, the present embodiments can use “target agent” to describe its behavior, while other agents are labeled as “other agent 1,” “other agent 2,” etc., to clearly outline interactions.

After the encoder, the present embodiments can obtain each agent embedding of [T,D], including rich context information from the scene.

In block 530, the map information, agent information, and semantic information can be fused into text-conditioned encodings using a cross-attention fusion module of the LTDS model.

In an embodiment, to fuse the map information, agent information, and semantic information into text-conditioned encodings 308 using a cross-attention fusion module 310 of the LTDS model 117, a model g, parameterized by θ, that governs the behavior of each of the N agents, producing fused trajectories 311

$${\{ {s}_{t : t + T}^{i} \}}_{i = 1}^{N}$$

that can be utilized. Each text-conditioned trajectory (e.g., fused trajectory 311)

$${s}_{t : t + T}^{i}$$

is generated by g_{θ}(cₜ, ψᵢ, e_{lang}), where ψᵢ is a set of control parameters unique to each agent, allowing for varied, user-aligned behaviors across different scenarios.

Training g on real-world driving data ensures that generated trajectories are both realistic and adaptable to user-defined scenarios, including text-conditioned variations, and symbolic variations.

The present embodiments can employ trajectory diffusion models (e.g., text-condition diffusion model 320) to enable realistic, text-conditioned outputs, drawing from recent advancements in controllable diffusion. The text-conditioned trajectory (e.g., fused trajectory 311) can be defined as τ=[τₐ, τₛ], where τₐ=[a₀, . . . , a_{T-1}] denotes the sequence of actions, and τₛ=[s₁, . . . , s_{T}] denotes the sequence of states. The text-condition diffusion model 320 predicts the action sequence τₐ, and the state sequence τₛ is derived from the initial state s₀ and dynamics f.

To capture spatiotemporal context, the present embodiments can apply cross-attention between each mentioned agent encoding 307 can include context embedding (augmented with positional embeddings) and the class token embedding (e.g., text encoding) output of the text encoder 304. This enables the cross-attention fusion module 310 to distinguish interactions among agents within the scene effectively.

In block 540, language-conditioned trajectories can be generated based on the text-conditioned encodings with a text-conditioned diffusion model of the LTDS model for performing downstream tasks based on the language-conditioned trajectories.

In an embodiment, the text-conditioned diffusion model 320 can process text condition 401, scene context 402 and noisy trajectories 403 to generate language-conditioned trajectory 119.

The text-conditioned diffusion model 320 can include a query-centric attention layer 411, agent-context cross-attention layer 413, and text cross-attention layer 415.

The query-centric attention layer 411 capture inter-agent relationships, allowing each agent to attend to other agents' future actions. The agent-context cross-attention layer 413 where each agent attends to its context embedding generated by the Scene Encoder, ensuring that the agent's behavior aligns with the spatiotemporal context of the environment. The text cross-attention layer 415 where if a language description is provided, each agent also attends to the language-conditioned embedding, incorporating condition from user-defined language inputs

In an embodiment, noisy trajectories can be generated with a forward noising process from a trajectory sampled from a data distribution from the input videos.

In an embodiment, starting with a real trajectory τ₁ sampled from the data distribution q(τ₀), a sequence of noisy trajectories (τ₁, τ₂, . . . , τ_{K}) is generated through a forward noising process, where each τₖ is obtained by adding Gaussian noise with variance β_{K}:

$$q ( {τ}_{1} : K \vert {τ}_{0} ) := {\prod }_{k = 1}^{K} q ( {τ}_{k} \vert {τ}_{k - 1} ) ,$$

where q(τ₁|τₖ₋₁):=N (τₖ; \sqrt{1−β_{kτ}_{ₖ₋₁}}, βₖI).

In an embodiment, the trajectories from the data distribution can be obscured to approximate a final noisy trajectory through obscured iterations. The process progressively obscures (e.g., masking) the data until the final noisy trajectory q(τₖ) approximates N (τₖ; 0, I) through past obscured iterations.

In an embodiment, the obscured iterations can be learned by modifying a mean prediction of agent behavior to reflect language-driven behavior.

In an embodiment, to generate language-conditioned trajectories 119, the model learns to reverse this noising process, gradually denoising τₖ back to τ₀ in a sequence of reverse steps. Each step in this reverse process incorporates the text encoding eₜₑₓₜ, modifying the mean prediction to reflect language-driven behavior:

p_{θ}(ιₖ₋₁|τₖ, c, eₜₑₓₜ):=N (τₖ₋₁; μ_{θ}(τₖ, k, c, eₜₑₓₜ), τₖ), where θ are learned parameters predicting the mean p at each reverse step, and Σₖ is a fixed schedule.

This iterative reverse process (e.g., training) yields a distribution over trajectories conditioned by both scene context and text, thus enabling the generation of plausible and directive-aligned future trajectories. As a result, a trained text-conditioned diffusion model 320 can be obtained.

During prediction, the model ultimately estimates a clean trajectory \hat{τ}₀, using \hat{τ}₀ to compute the mean μ as outlined. Through this method, the present embodiments enable flexible and text-responsive trajectory generation, creating rich and diverse simulations aligned with specified behaviors.

The present embodiments can output the control actions at each timestep for downstream tasks, and based on the dynamics model and the full states of all agents.

In block 550, closed loop training of the text-conditioned diffusion model can be performed with model-generated states.

In an embodiment, the model-generated states include predicted states of the actors within a scene based on trajectories obtained at real time and text-conditioned trajectories. The model-generated states can be generated with closed loop training of the text-conditioned diffusion model 320.

To perform the closed loop training, blocks 551-559 can be performed with the closed-loop diffusion trainer 323.

In block 551, at each training step of the closed loop training, a forward diffusion can be applied to perturb the ground truth trajectories. In block 553, to generate multiple candidate trajectories, the forward diffusion is followed by a one-step reverse diffusion. In block 555 and 557, the best candidate can be selected using a predefined distance function and executed the selected trajectory before repeating the process. In block 559, the final loss function between the executed and ground truth trajectories in the global coordinate space (e.g., traffic scene) can be is computed and minimized, allowing the model to learn how to recover from accumulated errors.

The closed-loop training can be described in the following:
perform Closed Loop Training:

For each trajectory in a dataset

$$𝒟 = {\{ {s}_{0 : T}^{( i )} \}}_{i = 1}^{N}$$

for each time step t=0 to T−Tᵣₑₚₗₐₙ, where Tᵣₑₚₗₐₙ is the planning horizon.
extract target sequence: s_{target}←s_{t:t+T}_{ᵣₑₚₗₐₙ}
perform forward diffusion:
sample noise level: τ~ [symbol] (K_{γ}, K), where K are the denoising steps and γ is a noise scale.
add noise: s_{τ}←\sqrt{α_{τ}}s_{target}+\sqrt{1−α_{τ}}∈, ∈~ [symbol] (0, I)
end forward diffusion
perform denoising and candidate selection
generate M candidate trajectories Ŝ^{(1:M)} using one-step denoising
select best sample trajectory

$${m}^{*} = arg {min}_{m} D ( {\hat{s}}^{( m )} , {s}_{target} ) ,$$

where D is a distance metric.
execute trajectory Ŝ^{(m*)} and update state.
end denoising and candidate selection
perform model update
compute loss:

$$ℒ = {‖ {\hat{s}}_{0 : T}^{( {m}^{*} )} - {s}_{0 : T} ‖}^{2}$$

update model parameters θ
end perform model update
end for end for
return model parameters θ
end Closed Loop Training.

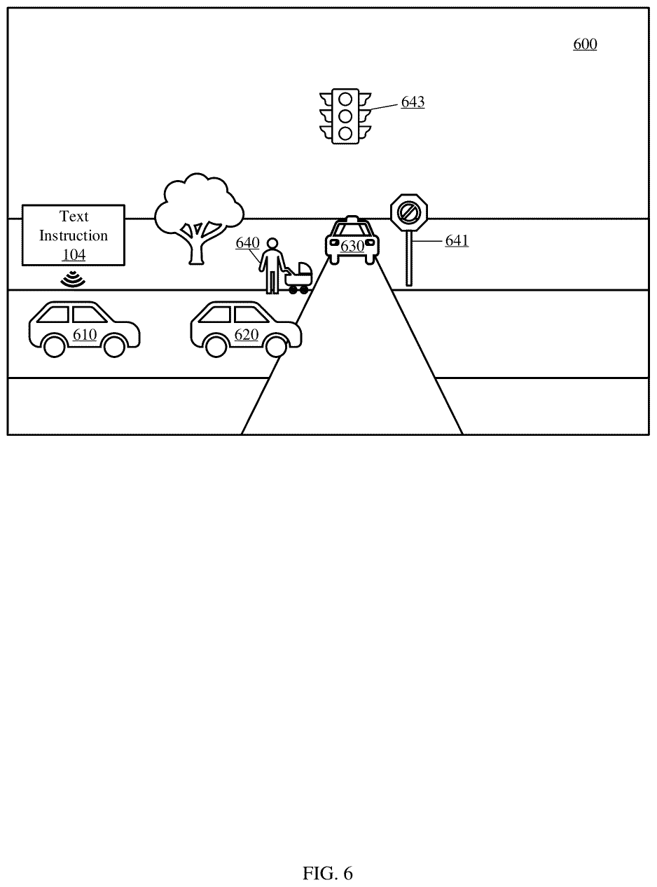

Referring now to FIG. 6, a block diagram shows a practical application of language-conditioned trajectory diffusion for closed-loop traffic simulation, in accordance with an embodiment of the present invention.

In an embodiment, in traffic scene 600, vehicle 610 can communicate with analytic server 106 through a network. Text instructions 104 can be communicated to vehicle 610 through an artificial intelligence (AI) agent that can communicate with the analytic server 106. The text instructions 104 can include commands to control vehicle 610 such as controlling the components of the vehicle (e.g., air quality control, entertainment components such as radio, etc.) and controlling the trajectory of the vehicle (e.g., speeding up, braking, change direction, etc.) through autonomous decision making.

Vehicle 610 can autonomously understand the traffic scene 600 and generate language-conditioned trajectories 119 based on the traffic scene. The language-conditioned trajectories 119 can include predictions of trajectories of the entities in the traffic scene 600. For example, the language-conditioned trajectories 119 can include the following: “vehicle (620) is in the intersection where pedestrian (640) is also crossing the intersection and taxi (630) is stopped behind one-way sign (641) as the light on (643) is red for taxi (630) and green for vehicle (620).”

In another embodiment, in traffic scene 600, vehicle 610 can simulate trajectories for the identified entities. In another embodiment, in traffic scene 600, based on the simulated trajectories of the identified entities, vehicle 610 can generate a trajectory to avoid the simulated trajectories of the identified entities and avoid collisions. In another embodiment, the vehicle 610 can be autonomously controlled based on the generated trajectory to avoid collisions.

By leveraging natural language conditioning, the present embodiments enable flexible control over diverse traffic scenarios, allowing for comprehensive evaluations and realistic behavioral simulations. This versatility ensures that the LTDS 117 can seamlessly adapt to a wide spectrum of practical autonomous driving scenarios, enhancing its applicability across various real-world conditions.

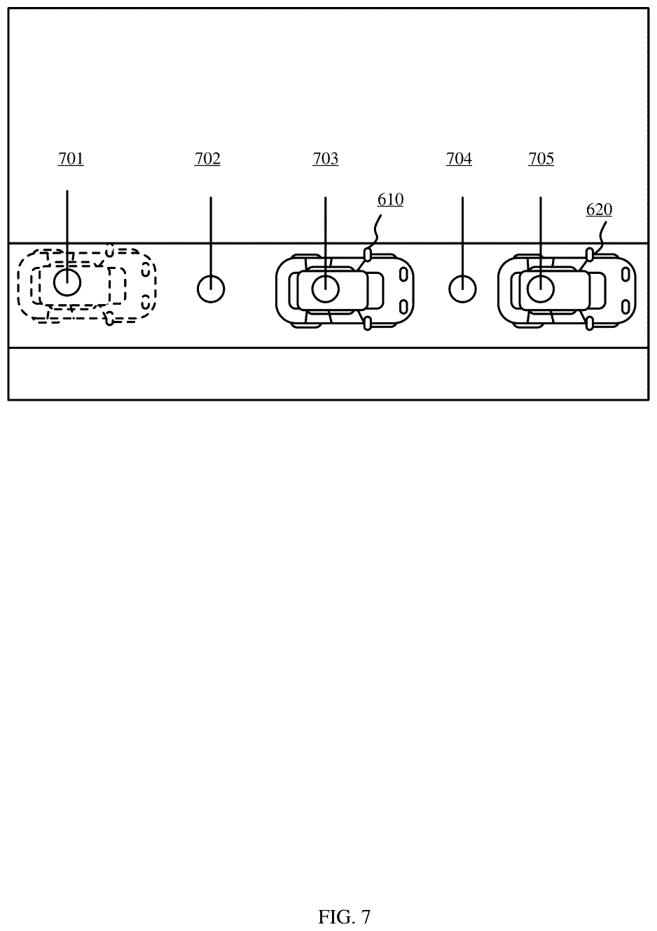

Referring now to FIG. 7, a block diagram showing closed-loop training for language-conditioned trajectory diffusion for closed-loop traffic simulation, in accordance with an embodiment of the present invention.

In an embodiment, vehicle 610 can be utilized for downstream tasks such as autonomous driving. Vehicle 610 can start from state 701 and can predict and move to states 702, 703, 704 and 705. States 701-705 include the vehicle 601 status (e.g., trajectories including speed, direction, etc.) and the environment status (e.g., conditions in the scene including other vehicles).

Vehicle 610 can generate text-conditioned simulations of the states (e.g., 701-705) of reactive agents and the ego vehicle (e.g., vehicle 610). The reactive agents (e.g., vehicle 620) include both realistic traffic participants and adversarial vehicles explicitly designed to provoke collisions with the ego vehicle. To ensure dynamic realism, all vehicle states and transitions follow unicycle dynamics. The ego vehicle's (e.g., 610) trajectory is generated by a dedicated planner utilized with the analytic server 106 that integrates historical data and map information, enabling informed and autonomous decision-making. Meanwhile, reactive agent behaviors are governed by the learned parameters of the text-conditioned diffusion model 320 trained on real-world data, allowing for naturalistic interactions. Adversarial vehicles, in contrast, are driven by an incentive function that minimizes their distance from the ego vehicle, increasing the likelihood of collisions. To facilitate precise scenario design, text instructions 104 define specific collision events (e.g., merge collisions), enabling detailed scenario generation and in-depth analysis.

During the autonomous driving process, vehicle 610 can predict that an undesirable event (e.g., collision) with vehicle 620 can happen on state 705. As such, the vehicle 610 can generate language-conditioned trajectory 119 to avoid vehicle 620. The states 701-705 can be used for the closed-loop training of the text-conditioned diffusion model 320.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment. However, it is to be appreciated that features of one or more embodiments can be combined given the teachings of the present invention provided herein.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended for as many items listed.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A method, comprising:
capturing multi-modality scene context information that includes map information and agent information for agents in input videos with a language-conditioned trajectory diffusion simulation (LTDS) model;
extracting spatiotemporal scene information based on semantic information from text instructions with the LTDS model;
fusing the map information, agent information, and semantic information using a cross-attention fusion module of the LTDS model into text-conditioned encodings;
generating language-conditioned trajectories based on the text-conditioned encodings with a text-conditioned diffusion model of the LTDS model; and
performing closed-loop training of the text-conditioned diffusion model while performing downstream tasks based on the language-conditioned trajectories.

2. The method of claim 1, wherein performing the closed-loop training further comprises perturbing ground truth trajectories with forward diffusion to generate noisy trajectories.

3. The method of claim 2, performing the closed-loop training further comprises further comprises generating candidate trajectories by denoising the noisy trajectories with one-step denoising.

4. The method of claim 3, performing the closed-loop training further comprises further comprises selecting a best candidate trajectory from the candidate trajectories based on a predefined distance function.

5. The method of claim 4, performing the closed-loop training further comprises updating model parameters of the text-conditioned diffusion model after executing the best candidate trajectory as the executed trajectory.

6. The method of claim 5, performing the closed-loop training further minimizing final loss function between the executed trajectory and the ground truth trajectories in a global coordinate space.

7. The method of claim 1, wherein the downstream tasks further comprises controlling an autonomous vehicle based on the language-conditioned trajectories and the text instructions through autonomous decision making.

8. A system, comprising:
a memory device;
one or more processor devices operatively coupled with the memory device to perform operations including:
capturing multi-modality scene context information that includes map information and agent information for agents in input videos with a language-conditioned trajectory diffusion simulation (LTDS) model;
extracting spatiotemporal scene information based on semantic information from text instructions with the LTDS model;
fusing the map information, agent information, and semantic information using a cross-attention fusion module of the LTDS model into text-conditioned encodings;
generating language-conditioned trajectories based on the text-conditioned encodings with a text-conditioned diffusion model of the LTDS model; and
performing closed-loop training of the text-conditioned diffusion model while performing downstream tasks based on the language-conditioned trajectories.

9. The system of claim 8, wherein performing the closed-loop training further comprises perturbing ground truth trajectories with forward diffusion to generate noisy trajectories.

10. The system of claim 9, performing the closed-loop training further comprises further comprises generating candidate trajectories by denoising the noisy trajectories with one-step denoising.

11. The system of claim 10, performing the closed-loop training further comprises further comprises selecting a best candidate trajectory from the candidate trajectories based on a predefined distance function.

12. The system of claim 11, performing the closed-loop training further comprises updating model parameters of the text-conditioned diffusion model after executing the best candidate trajectory as the executed trajectory.

13. The system of claim 12, performing the closed-loop training further minimizing final loss function between the executed trajectory and the ground truth trajectories in a global coordinate space.

14. The system of claim 8, wherein the downstream tasks further comprises controlling an autonomous vehicle based on the language-conditioned trajectories and the text instructions through autonomous decision making.

15. A non-transitory computer program product comprising a computer-readable storage medium including a program code, wherein the program code when executed on a computer causes the computer to perform operations including:
capturing multi-modality scene context information that includes map information and agent information for agents in input videos with a language-conditioned trajectory diffusion simulation (LTDS) model;
extracting spatiotemporal scene information based on semantic information from text instructions with the LTDS model;
fusing the map information, agent information, and semantic information using a cross-attention fusion module of the LTDS model into text-conditioned encodings;
generating language-conditioned trajectories based on the text-conditioned encodings with a text-conditioned diffusion model of the LTDS model; and
performing closed-loop training of the text-conditioned diffusion model while performing downstream tasks based on the language-conditioned trajectories.

16. The non-transitory computer program product of claim 15, wherein performing the closed-loop training further comprises perturbing ground truth trajectories with forward diffusion to generate noisy trajectories.

17. The non-transitory computer program product of claim 16, performing the closed-loop training further comprises further comprises generating candidate trajectories by denoising the noisy trajectories with one-step denoising.

18. The non-transitory computer program product of claim 17, performing the closed-loop training further comprises further comprises selecting a best candidate trajectory from the candidate trajectories based on a predefined distance function.

19. The non-transitory computer program product of claim 18, performing the closed-loop training further comprises updating model parameters of the text-conditioned diffusion model after executing the best candidate trajectory.

20. The non-transitory computer program product of claim 15, wherein the downstream tasks further comprises controlling an autonomous vehicle based on the language-conditioned trajectories and the text instructions.
